(19) United States
(12) Patent Application Publication
(10) Pub. No.: US 2025/0113677 A1
(43) Pub. Date: Apr. 3, 2025

(54) High-contrast display screen LED device and manufacturing method therefor

(71) Applicant: South China University of Technology, Guangzhou City, Guangdong (CN)

(72) Inventors: Zongtao LI, Guangzhou City, Guangdong (CN); Xinrui DING, Guangzhou City, Guangdong (CN); Jiasheng LI, Guangzhou City, Guangdong (CN); Changkun SHAO, Guangzhou City, Guangdong (CN)

(21) Appl. No.: 18/723,738

(22) PCT Filed: Nov. 15, 2022
(86) PCT No.: PCT/CN2022/131994

§ 371 Date: Jun. 24, 2024

(30) Foreign Application Priority Data
Dec. 22, 2021 (CN) 202111584082.5

(51) Int. Cl. H10H 20/855; H10H 20/01; H10H 20/85; H10H 20/857

(52) U.S. Cl. CPC H10H 20/855; H10H 20/0363; H10H 20/0364; H10H 20/8506; H10H 20/857

(57) ABSTRACT

A high-contrast display screen LED device and a manufacturing method therefor are disclosed. The LED device includes a housing including a bottom and a side wall, the bottom and the side wall forming a unit cavity with an opening; an LED chip arranged in the unit cavity; a transparent encapsulation layer covering the LED chip; a lens arranged on the encapsulation layer, a position of the lens is corresponding to a position of the LED chip; and an opaque light shield layer covering the encapsulation layer and partially wrapped around the lens; light from the LED chip is emitted after being converged by the lens.

### CROSS-REFERENCE TO RELATED APPLICATIONS

This application is a national stage filing under 35 U.S.C. § 371 of international application number PCT/CN2022/131994, filed Nov. 15, 2022, which claims priority to Chinese patent application No. 202111584082.5 filed Dec. 22, 2021. The contents of these applications are incorporated herein by reference in their entirety.

### TECHNICAL FIELD

The present disclosure relates to the technical field of LEDs, and more particularly, to a high-contrast display screen LED device and a manufacturing method therefor.

### BACKGROUND

LED display screen has been widely used in society, but the display screen on the market generally has a low contrast ratio. The main reason for this problem is that a LED chip on the display screen reflects more external light sources. In order to solve this problem, many products are blackened by adding black materials such as carbon powder black paint to reduce reflection of the external light sources. However, in order to improve the contrast, excessive blackening easily causes light emitted by the LED itself to be absorbed, resulting in low efficiency of the device, which is a technical contradiction at present.

### SUMMARY

In order to at least some extent solve one of the technical problems existing in the existing technology, an object of the present disclosure is to provide a high-contrast display screen LED device and a manufacturing method therefor.

A technical scheme disclosed in the present disclosure is as follows:

A high-contrast display screen LED device comprises:

a housing including a bottom and a side wall, where the bottom and the side wall form a unit cavity with an opening;

an LED chip arranged in the unit cavity;

a transparent encapsulation layer covering the LED chip;

a lens arranged on the encapsulation layer, where a position of the lens is corresponding to a position of the LED chip; and

an opaque light shield layer covering the encapsulation layer and partially wrapped around the lens;

light from the LED chip is emitted after being converged by the lens.

Further, the lens is in a frustum shape, and the light from the LED chip is directed into a first surface of the lens, and then emitted from a second surface of the lens emitted after being converged by the lens; and the first surface has an area larger than that of the second surface.

Further, a height of the second surface relative to the bottom is higher than a height of the side wall relative to the bottom.

Further, a height of the light shield layer relative to the bottom is lower than a height of the side wall relative to the bottom.

Further, the bottom is provided with a metal pin, the LED chip is connected to the metal pin through a metal lead, and the encapsulation layer covers the metal pin and the metal lead.

Further, the lens has a refractive index higher than that of the light shield layer.

Further, the light shield layer includes several layers of opaque glue.

Further, the light shield layer is made of a transparent colloidal material mixed with a non-transparent material, and the non-transparent material includes titanium dioxide, silicon dioxide, carbon black or graphite.

Further, a material of the lens includes a glass material, a polycarbonate material or a PMMA material; and

a material of the encapsulation layer includes epoxy resin, silicone resin or a resin mixed material.

Another technical scheme disclosed in the present disclosure is as follows:

A manufacturing method for the high-contrast display screen LED device as described above, includes the following steps of:

placing an LED chip in a preset position in a unit cavity, and fixing the LED chip on a housing;

dispensing a surface of the LED chip to make a non-opaque first colloid cover the LED chip, and curing the device after dispensing;

placing a lens on the first colloid; and

dispensing a surface of the first colloid to make a non-opaque second colloid cover the first colloid, and curing the device after dispensing.

The present disclosure has the beneficial effects that: according to the present disclosure, the contrast is improved by focusing emergent light from the LED by the lens; and a proper black ratio is provided, such that adverse effects caused by an excessive blackening treatment can be avoided while a high contrast is maintained.

### BRIEF DESCRIPTION OF THE DRAWINGS

In order to illustrate the technical schemes in the embodiments of the present disclosure or in the related art more clearly, the drawings used in the description of the embodiments or the existing technology will be briefly described below. Obviously, the drawings in the following description are merely some embodiments recorded in the present disclosure. For those of ordinary skills in the art, other drawings may also be obtained based on these drawings without going through any creative work.

FIG. 1 is a cross-sectional view of a high-contrast display screen LED device according to Embodiment 1 of the present disclosure;

FIG. 2 is a structural diagram of an LED device after lead welding in a manufacturing method for an LED device according to Embodiment 1 of the present disclosure;

FIG. 3 is a structural diagram of the LED device after first dispensing in the manufacturing method for the LED device according to Embodiment 1 of the present disclosure;

FIG. 4 is a structural diagram of a built-in lens in the manufacturing method for the LED device according to Embodiment 1 of the present disclosure;

FIG. 5 is a flow chart of steps of a manufacturing method for an LED device according to the embodiments of the present disclosure;

FIG. 6 is a schematic diagram of a metal lead and a metal pin according to the embodiments of the present disclosure;

FIG. 7 is a cross-sectional view of a high-contrast display screen LED device with a lens according to Embodiment 3 of the present disclosure;

FIG. 8 is a cross-sectional view of a high-contrast display screen LED device with a lens according to Embodiment 4 of the present disclosure;

FIG. 9 is a flow chart of steps of a manufacturing method for an LED device according to Embodiment 4 of the present disclosure;

FIG. 10 is a cross-sectional view of a high-contrast display screen LED device with a lens according to Embodiment 5 of the present disclosure;

FIG. 11 is a flow chart of steps of a manufacturing method for an LED device according to Embodiment 5 of the present disclosure;

FIG. 12 is a cross-sectional view of a high-contrast display screen LED device with a lens according to Embodiment 6 of the present disclosure; and

FIG. 13 is an entire structural diagram of a high-contrast display screen LED device according to the embodiments of the present disclosure.

Reference numerals: 100-lens; 200-light shield layer; 300-housing; 400-LED chip; 500—encapsulation layer; 301-metal lead; and 302-metal pin.

### DETAILED DESCRIPTION

The embodiments of the present disclosure will be described in detail hereinafter. Examples of the embodiments are shown in the drawings. The same or similar reference numerals throughout the drawings denote the same or similar elements or elements having the same or similar functions. The embodiments described below by reference to the accompanying drawings are exemplary and are intended only to explain the present disclosure and are not to be construed as limiting the present disclosure. For the step numbers in the following embodiments, they are only set for convenience of explanation, the order between the steps is not limited, and the execution order of each step in the embodiments may be adaptively adjusted according to the understanding of those skilled in the art.

In the description of the present disclosure, it should be understood that the orientation or position relation related to the orientation description, such as the orientation or position relation indicated by the upper, lower, front, rear, left, right, etc., is based on the orientation or position relation shown in the drawings, which is only used for convenience of description of the present disclosure and simplification of description instead of indicating or implying that the indicated device or element must have a specific orientation, and be constructed and operated in a specific orientation, and thus shall not be understood as a limitation to the present disclosure.

In the description of the present disclosure, the meaning of “several” refers to be one or more, and the meaning of “multiple” refers to be more than two. The meanings of “greater than, less than, more than, etc.,” are understood as not including this number, while the meanings of “above, below, within, etc.,” are understood as including this number. If “first” and “second” are described, the descriptions are used for the purpose of distinguishing the technical features only, and cannot be understood as indicating or implying relative importance, or implicitly indicating the number of technical features indicated thereby, or implicitly indicating the order of technical features indicated thereby.

In the description of the present disclosure, unless otherwise explicitly defined, words such as setting, mounting and connecting should be understood a broad sense, and those skilled in the art can reasonably determine the specific meanings of the above words in the present disclosure in combination with the specific contents of the technical schemes.

### Embodiment 1

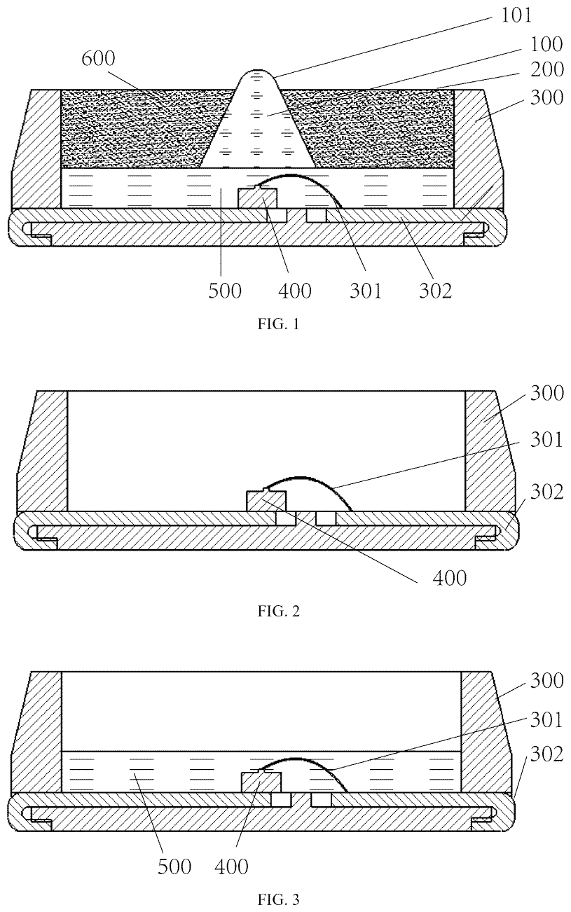

As shown in FIG. 1 and FIG. 13, this embodiment provides a high-contrast display screen LED device, including:

a housing 300 including a bottom and a side wall, where the bottom and the side wall form a unit cavity with an opening;

an LED chip 400 arranged in the unit cavity;

a transparent encapsulation layer 500 covering the LED chip 400;

a lens 100 arranged on the encapsulation layer 500, where a position of the lens 100 is corresponding to a position of the LED chip 400; and

an opaque light shield layer 200 covering the encapsulation layer 500 and partially wrapped around the lens 100;

light from the LED chip 400 is emitted after being converged by the lens 100.

In this embodiment, the position of the lens 100 corresponding to the position of the LED chip 400 means that: the lens 100 is arranged above the LED chip 400, but it should be noted that it is not limited to this positional relationship, as long as the light emitted by the chip can be converged and emitted through the lens.

Further, as an alternative embodiment, the lens 100 is in a frustum shape, and the light from the LED chip 400 is directed into a first surface of the lens 100, and then emitted from a second surface of the lens 100 after being converged by the lens 100; and the first surface has an area larger than that of the second surface. The second surface may be a plane or a curved surface.

A projection area of an upper surface of the lens 100 is small, while a projection area of a lower surface of the lens 100 is large. The light are incident from a lower side of the lens and enters the air after being converged by the lens 100, so as to increase the brightness and improve the contrast.

Further, as an alternative embodiment, a height of the second surface relative to the bottom is lower than a height of the side wall relative to the bottom.

Further, as an alternative embodiment, a height of the light shield layer 200 relative to the bottom is lower than a height of the side wall relative to the bottom.

Further, as an alternative embodiment, the bottom is provided with a metal pin, the LED chip 400 is connected to the metal pin 302 through a metal lead, and the encapsulation layer 500 covers the metal pin 302 and the metal lead 301.

PLCC encapsulation is adopted, where materials of the metal lead 301 and the metal lead 302 include but are not limited to copper, aluminum, iron and various alloys thereof.

Further, as an alternative embodiment, the lens 100 has a refractive index higher than that of the light shield layer 200.

Further, as an alternative embodiment, the light shield layer 200 includes several layers of opaque glue.

The light shield layer 200 may be a single layer or a plurality of layers, a form of the light shield layer 200 includes, but is not limited to, black glue, opaque white glue, white glue/black glue multilayer structure, and glue with a refractive index lower than that of the lens 100.

Further, as an alternative embodiment, the light shield layer 200 is made of a transparent colloidal material mixed with a non-transparent material, and the non-transparent material includes titanium dioxide, silicon dioxide, carbon black or graphite.

The light shield layer 200 is made of a transparent colloidal material mixed with a non-transparent material, and the non-transparent material includes titanium dioxide, silicon dioxide, carbon black or graphite. The mixed non-transparent material includes, but is not limited to titanium oxide, silicon dioxide, carbon black or graphite.

Further, as an alternative embodiment, a material of the lens 100 includes a glass material, a polycarbonate material or a PMMA material; and a material of the encapsulation layer 500 includes epoxy resin, silicone resin or a resin mixed material.

The material of the lens 100 is a transparent material with excellent light transmission performance, with a light transmittance of 80%-100%, and a refractive index higher than that of the surrounding opaque glue 200. The material includes, but is not limited to glass, polycarbonate (PC), PMMA or other materials.

As shown in FIG. 5, with respect to the LED device above, this embodiment also provides a manufacturing method for an LED device, including the following steps.

At step S101, an LED chip is placed, where an RBG three-color LED chip 400 is respectively placed in designated positions in a housing 300, as shown in FIG. 2.

At step S102, lead welding is carried out, where the LED chip is fixed on the housing, then positive and negative electrodes of the LED chip 400 are correspondingly welded with positive and negative metal pins 302 of a lead frame through the metal lead 301. A welding temperature needs to be at least 100° C., as shown in FIG. 2.

At step S103, first dispensing is carried out, where a high-precision dispensing head is used to dispense glue on a surface of the LED chip 400. The glue used is epoxy resin, and the glue needs to at least cover the LED chip 400. The device after dispensing is put into an oven for curing, and a curing temperature needs to be at least 45° C., as shown in FIG. 3.

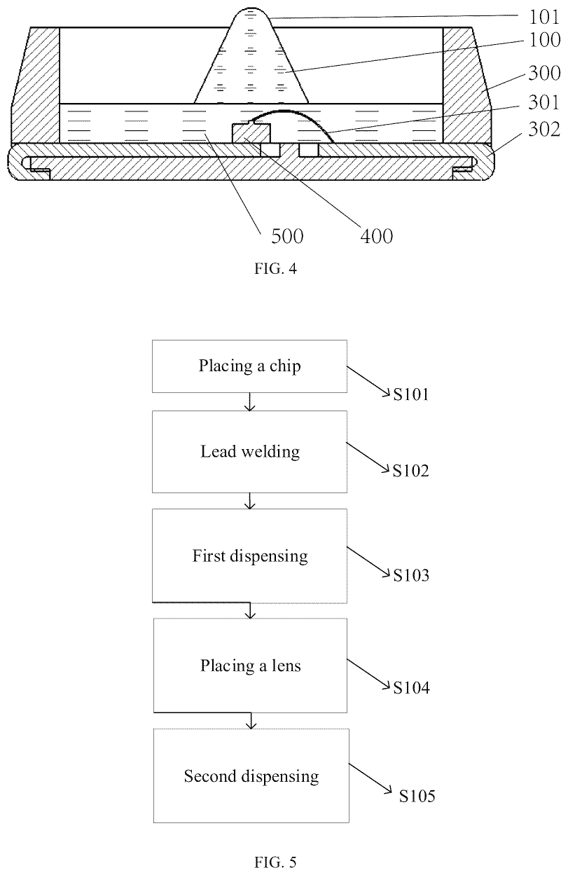

At step S104, the lens is placed, where the lens 100 is arranged above a non-opaque glue 500, as shown in FIG. 4.

At step S105, second dispensing is carried out, where the opaque glue 500 is added to an upper part of the non-opaque glue, and the glue needs to cover the non-opaque glue 200 and not exceed a surface of the housing. The device after dispensing is put into an oven for curing, and a curing temperature needs to be at least 80° C. If the opaque glue 200 is a multi-layer colloid, it needs to be further cured by layer dispensing, as shown in FIG. 1.

### Embodiment 2

As shown in FIG. 1, this embodiment provides a high-contrast display screen LED device with a lens, including a housing 300 and a lens 100.

The lens 100 is embedded in a top end of the housing 300, and a non-opaque encapsulation layer 500 is filled between the lens 100 and an LED chip 400. The encapsulation layer needs to at least cover the LED chip 400. Other spaces inside the housing 300 are filled with an opaque light shield layer 200. The opaque light shield layer 200 needs to at least cover the non-opaque encapsulation layer 500 and not exceed an upper opening of the housing 300. The LED chip 400 is connected to a metal lead 301, and the metal lead 301 is connected to a metal lead 302 inside the housing 300 to communicate with an external control circuit. Materials of the metal lead 301 and the metal pin 302 encapsulated by PLCC are Al and Au respectively. In this embodiment, the lens 100 focuses light emitted from the LED chip 400 to improve the contrast, and at the same time, a proper black ratio is provided. On this basis, it can avoid adverse effects caused by excessive blackening while a high contrast is maintained.

In some alternative embodiments, the lens 100 is a spherical lens, and a material of the lens 100 is a PC material with good light-transmission property, which can improve light-transmission efficiency of the device.

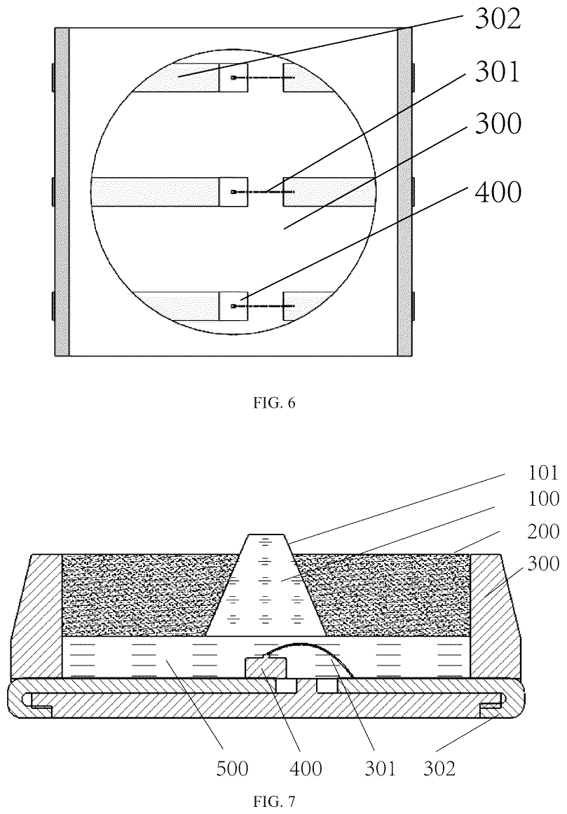

In some alternative embodiments, PLCC encapsulation is adopted for encapsulation, and the LED chip is connected to the control circuit through the metal lead 301 and the metal pin 302, with a total of 32 leads. The device is welded by adopting a reflow soldering process, which requires a special welding set, and the lead welding is as shown in FIG. 6.

The LED device of this embodiment is very suitable for use in the case of large ambient light, and is used for displaying characters, pictures and playing and publicizing multimedia programs. Meanwhile, the device of this embodiment is also suitable for indoor environment, and also has high contrast. In addition, the LED device of this embodiment has good sealing performance and can isolate water and oxygen. Compared with other similar products, the LED device of in this embodiment has a low a blackening part and a weak heat absorption capacity, so the LED device can work stably for a long time in summer and daytime. In conclusion, the LED device of this embodiment has high reliability.

With respect to the LED device above, this embodiment also provides a manufacturing method for an LED device, including the following steps.

At step S201, an LED chip is placed, where an RBG three-color LED chip 400 is respectively placed in designated positions in a housing 300.

At step S202, lead welding is carried out, where the LED chip is fixed on the housing, then one end of a metal lead 301 is connected to an electrode of the LED chip, and the other end of the metal lead is welded to a metal pin 302 at one side of the housing.

At step S203, first dispensing is carried out, where a high-precision dispensing head is used to dispense glue on a surface of the LED chip 400. The glue used is epoxy resin, and the glue needs to cover the entire LED chip 400 and the metal lead 301 above. The device after dispensing is put into an oven for curing, a curing temperature needs to be at least 150° C., and the curing lasts for 0.5 hour.

At step S204, the lens is placed, where the lens 100 is arranged above an epoxy resin layer.

At step S205, second dispensing is carried out, where the high-precision dispensing head is used to dispense glue on the surface of the LED chip. The glue used is opaque glue, and the glue needs to cover the non-opaque glue and not exceed a surface of the housing. The device after dispensing is put into an oven for curing, a curing temperature needs to be at least 150° C., and the curing lasts for 0.5 hour.

### Embodiment 3

As shown in FIG. 7, this embodiment provides a high-contrast display screen LED device with a lens. The LED device in Embodiment 3 is mostly the same as the LED device in Embodiment 2, except that: the lens 100 is different in shape, and an upper surface (i.e., a second surface) of the lens 100 in Embodiment 3 is smooth.

### Embodiment 4

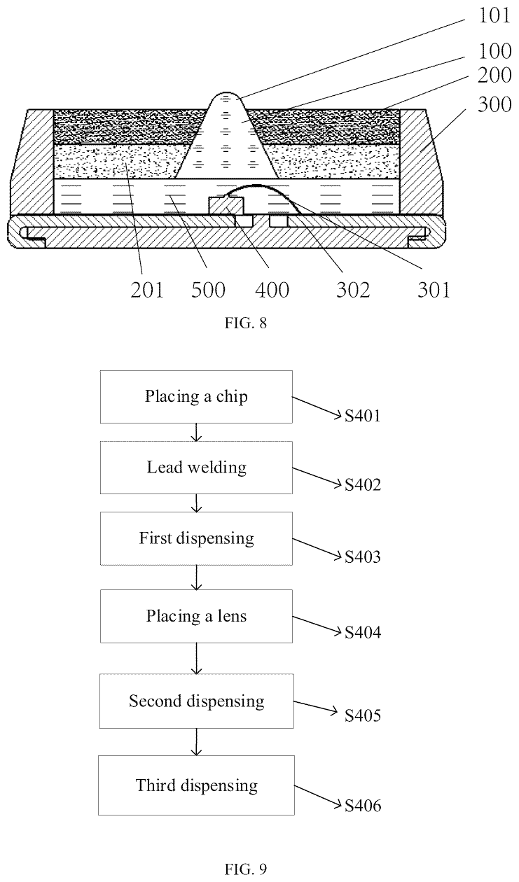

As shown in FIG. 8, this embodiment provides a high-contrast display screen LED device with a lens. The LED device in Embodiment 4 is mostly the same as the LED device in Embodiment 2, except that: a layer of non-transparent glue 201 is added to the encapsulation layer 500, and the non-transparent glue 201 is covered with a light shield layer 200.

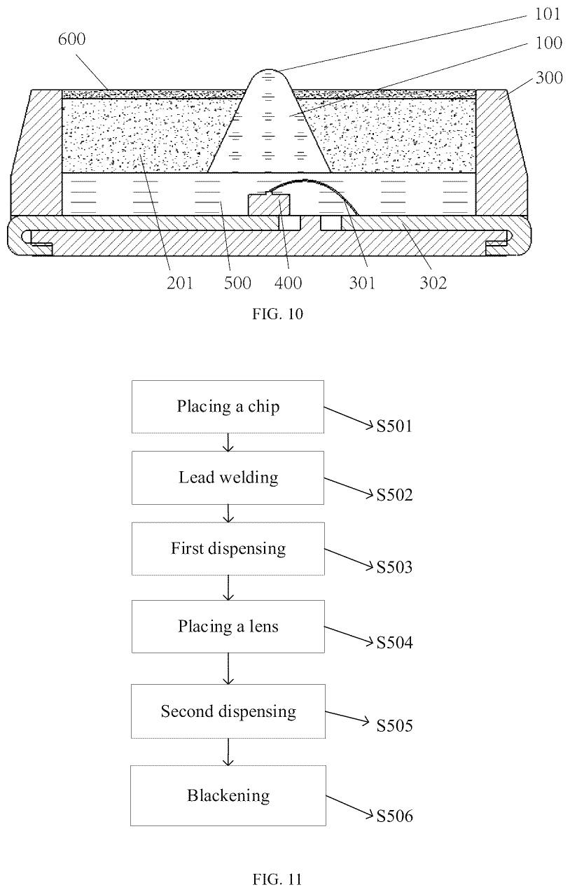

As shown in FIG. 9, this embodiment provides a high-contrast display screen LED device with a lens, including the following steps.

At step S401, an LED chip is placed, where an RBG three-color LED chip 400 is respectively placed in designated positions in a housing 300.

At step S402, lead welding is carried out, where the LED chip is fixed on the housing, then one end of a metal lead 301 is connected to an electrode of the LED chip, and the other end of the metal lead is welded to a metal pin 302 at one side of the housing.

At step S403, first dispensing is carried out, where a high-precision dispensing head is used to dispense glue on a surface of the LED chip 400. The glue used is epoxy resin, and the glue needs to cover the entire LED chip 400 and the metal lead 301 above. The device after dispensing is put into an oven for curing, a curing temperature needs to be at least 150° C., and the curing lasts for 0.5 hour.

At step S404, the lens is placed, where the lens 100 is arranged above an epoxy resin layer 500.

At step S405, second dispensing is carried out, where the high-precision dispensing head is used to dispense glue on the surface of the LED chip. Other non-transparent glue 201 is added to the encapsulation layer 500, and the other non-transparent glue 201 added covers the encapsulation layer 500, as shown in FIG. 8.

At step S406, third dispensing is carried out, where a non-transparent glue (light shield layer 200) is added, and the light shield layer 200 is covered with the other non-transparent glue 201.

### Embodiment 5

As shown in FIG. 10, this embodiment provides a high-contrast display screen LED device with a lens. The LED device in Embodiment 5 is mostly the same as the LED device in Embodiment 4, except that: a layer of non-transparent glue 201 is added to the encapsulation layer 500, and a top of the non-transparent glue 201 is blackened to form a blackened layer 600. The non-transparent glue 201 and the blackened layer 600 form a light shield layer.

As shown in FIG. 11, this embodiment provides a high-contrast display screen LED device with a lens, including the following steps.

At step S501, an LED chip is placed, where an RBG three-color LED chip 400 is respectively placed in designated positions in a housing 300.

At step S502, lead welding is carried out, where the LED chip is fixed on the housing, then one end of a metal lead 301 is connected to an electrode of the LED chip, and the other end of the metal lead is welded to a metal pin 302 at one side of the housing.

At step S503, first dispensing is carried out, where a high-precision dispensing head is used to dispense glue on a surface of the LED chip 400. The glue used is epoxy resin, and the glue needs to cover the entire LED chip 400 and the metal lead 301 above. The device after dispensing is put into an oven for curing, a curing temperature needs to be at least 150° C., and the curing lasts for 0.5 hour.

At step S504, the lens is placed, where the lens 100 is arranged above an epoxy resin layer 500.

At step S505, second dispensing is carried out, where the high-precision dispensing head is used to dispense glue on the surface of the LED chip. Other non-transparent glue 201 is added to the encapsulation layer 500, and the other non-transparent glue 201 added covers the encapsulation layer 500.

At step S506, the top of the other non-transparent glue 201 is blackened to form the blackened layer 600.

### Embodiment 6

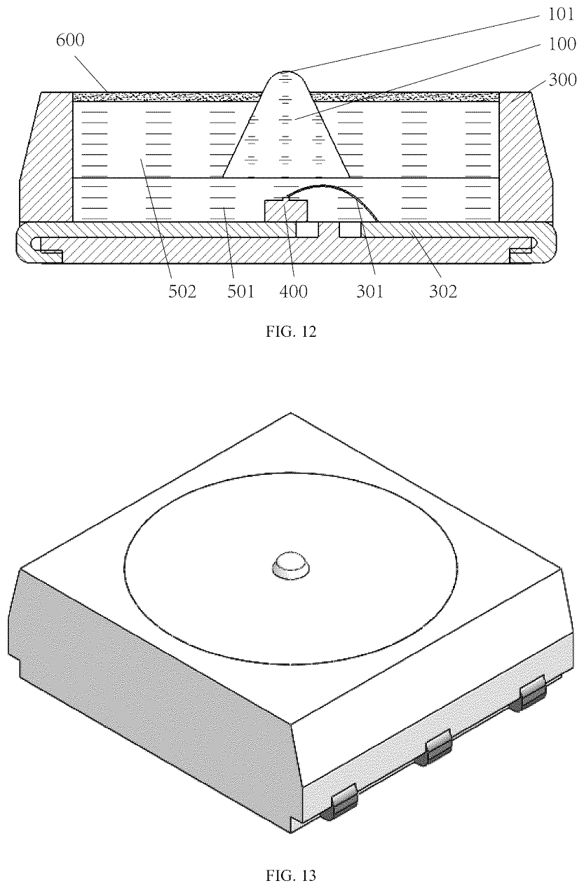

As shown in FIG. 12, this embodiment provides a high-contrast display screen LED device with a lens. The LED device in Embodiment 6 is mostly the same as the LED device in Embodiment 5, except that: a layer of non-opaque glue 502 is added to the encapsulation layer 501, and a top of the non-opaque glue 502 is blackened to form a blackened layer 600. The non-opaque glue 502 and the blackened layer 600 form a light shield layer.

The encapsulation layer 501 and the non-opaque glue 502 are made of the same material, and a refractive index of the material is lower than a refractive index of the lens 100.

In the description of this specification, the descriptions to the reference terms “one embodiment/example”, “another embodiment/example”, or “some embodiments/examples” mean that the specific features, structures, materials or characteristics described in connection with this embodiment or example are included in at least one embodiment or example of the present disclosure. In the specification, the schematic representation of the above terms does not necessarily mean the same embodiment or example. Moreover, the specific features, structures, materials or characteristics described may be combined in any one or more embodiments or examples in a suitable manner.

Although the embodiments of the present disclosure have been shown and described, those of ordinary skills in the art should understand that: various changes, amendments, substitutions and modifications can be made to these embodiments without departing from the principles and purposes of the present disclosure, and the scope of the present disclosure is limited by the claims and equivalents thereof.

The foregoing describes the preferred embodiments of the present disclosure in detail, but the present disclosure is not limited to the embodiments, those skilled in the art can make various equal deformations or replacements without departing from the gist of the present disclosure, and these equal deformations or replacements shall all fall within the scope limited by the claims of the present disclosure.

1. A high-contrast display screen LED device, comprising:
a housing comprising a bottom and a side wall, wherein the bottom and the side wall form a unit cavity with an opening;
an LED chip arranged in the unit cavity;
a transparent encapsulation layer covering the LED chip;
a lens arranged on the encapsulation layer, wherein a position of the lens is corresponding to a position of the LED chip; and
an opaque light shield layer covering the encapsulation layer and partially wrapped around the lens;
wherein light from the LED chip is emitted after being converged by the lens.

2. The high-contrast display screen LED device according to claim 1, wherein the lens is in a frustum shape, and the light from the LED chip is directed into a first surface of the lens, and then emitted from a second surface of the lens after being converged by the lens; and the first surface has an area larger than that of the second surface.

3. The high-contrast display screen LED device according to claim 2, wherein a height of the second surface relative to the bottom is higher than a height of the side wall relative to the bottom.

4. The high-contrast display screen LED device according to claim 1, wherein a height of the light shield layer relative to the bottom is lower than a height of the side wall relative to the bottom.

5. The high-contrast display screen LED device according to claim 1, wherein the bottom is provided with a metal pin, the LED chip is connected to the metal pin through a metal lead, and the encapsulation layer covers the metal pin and the metal lead.

6. The high-contrast display screen LED device according to claim 1, wherein the lens has a refractive index higher than that of the light shield layer.

7. The high-contrast display screen LED device according to claim 1, wherein the light shield layer comprises several layers of opaque glue.

8. The high-contrast display screen LED device according to claim 1, wherein the light shield layer is made of a transparent colloidal material mixed with a non-transparent material, and the non-transparent material comprises titanium dioxide, silicon dioxide, carbon black or graphite.

9. The high-contrast display screen LED device according to claim 1, wherein a material of the lens comprises a glass material, a polycarbonate material or a PMMA material; and
a material of the encapsulation layer comprises epoxy resin, silicone resin or a resin mixed material.

10. A manufacturing method for the high-contrast display screen LED device according to claim 1, comprising the following steps of:
placing an LED chip in a preset position in a unit cavity, and fixing the LED chip on a housing;
dispensing a surface of the LED chip to make a non-opaque first colloid cover the LED chip, and curing the device after dispensing;
placing a lens on the first colloid; and
dispensing a surface of the first colloid to make a non-opaque second colloid cover the first colloid, and curing the device after dispensing.
